(19) United States
(12) Patent Application Publication
(10) Pub. No.: US 2008/0055451 A1
(43) Pub. Date: Mar. 6, 2008

(54) Solid-state imaging device and imaging apparatus

(75) Inventor: Hideo Kanbe, Kanagawa (JP)

Correspondence Address: ROBERT J. DEPKE;LEWIS T. STEADMAN, ROCKEY, DEPKE & LYONS, LLC, SUITE 5450 SEARS TOWER, CHICAGO, IL, 60606-6306, US

(73) Assignee: SONY CORPORATION

(21) Appl. No.: 11/891,257

(22) Filed: Aug. 9, 2007

(30) Foreign Application Priority Data
Aug. 29, 2006 (JP) P2006-231505

(51) Int. Cl. H04N 5/335

(52) U.S. Cl. 348/311

(57) ABSTRACT

A solid-state imaging device includes a signal charge detection unit converting signal charges into voltage to be outputted, which have been obtained by photoelectrically converting incident light, and in which the signal charge detection unit arranges a drive transistor having a carbon nanotube channel over a channel region between an output gate and a reset gate of a solid-state imaging device through an insulating film.

### CROSS REFERENCE TO RELATED APPLICATIONS

The present invention contains subject matter related to Japanese Patent Application JP 2006-231505 filed in the Japanese Patent Office on Aug. 29, 2006, the entire contents of which being incorporated herein by reference.

### BACKGROUND OF THE INVENTION

1. Field of the Invention

The invention relates to a solid-state imaging device and an imaging apparatus in which a transistor using carbon nanotube is used in a charge detection circuit.

2. Description of the Related Art

As a signal charge detection unit of a solid-state imaging device, there is a detection unit of a floating diffusion layer (hereinafter, referred to as FD, FD is an abbreviation of “floating diffusion”), and the type is widely used as a charge detection unit of a CCD (Charge Coupled Device) type imaging device, a charge voltage conversion unit of a CMOS sensor pixel and the like. In the type, there is necessity of canceling KTC noise (thermal noise peculiar to the CCD) by a correlation double sampling (CDS) and the like and there are constraints such that relatively higher voltage is necessary for output unit operation voltage at a later stage, however, it is easy to obtain high conversion gain in this type.

As a primary charge detection type other than the FD, there is a floating gate (hereinafter, referred to as FG, FG is an abbreviation of “Floating Gate”) type. The FG type is chiefly used as a charge detection unit of the CCD device, and for example in a horizontal CCD termination part of the CCD imaging device, a FG potential varies according to an signal charge amount by transferring signal charges to a CCD channel under a floating gate for charge detection which is reset to a certain potential, and the FG is connected to a gate of an output MOSFET (FET: Field Effect Transistor), and channel current of the output MOSFET is modulated according to the signal amount in principle. In this type, owing to the connection of a transistor for resetting a FG portion and the area of the FG portion, the charge detection capacity tends to be increased as compared with the FD type, as a result, the charge detection unit having high conversion efficiency is hardly obtained. However, since it is easy to set operation voltage of the output unit at a later state to be lower and it is nondestructive reading, there are merits that a means for improving SN of the detection circuit by arranging plural FGs and the like.

As charge detection types other then the above, there are a method of directly reading current and a CMD (Charge Modulation Device) type charge detection unit. The method of directly reading current is a method in which signal current is allowed to flow in a PN junction of the CCD termination and voltage of both ends of R of a current path, which is considered as an inferior method in view of SN. In the CMD type charge detection type, by utilizing that a surface potential of an upper part of a buried channel CCD (BCCD) and a well potential at a lower part are modulated by signal charges flowing in the BCCD, a transistor having a conducting type reverse to the CCD is formed in a form of crossing the BCCD, in which signal components are obtained from current flowing in the reverse-conducting type transistor. Though the method has merits that the nondestructive reading is possible and the like, however, the structure is complicated and the manufacturing margin is low on the design.

Some technologies using a carbon nanotube (hereinafter, referred to as CNT) transistor for optical sensing are proposed. As one of them, there is an example in which a carbon nanotube FET on a silicon oxide (SiO₂)/silicon (Si) structure is applied to an optical sensor. This is a technology that photoelectric conversion itself is performed inside silicon (Si), and potential change at the surface of the silicon (Si) by generated charges modulates a channel region potential of the carbon nanotube FET at the upper part of an oxide film (for example, refer to “Application of Carbon nanotube SET/FET to Sensor” attributed to Kazuhiko Matsuda (Osaka University), papers of Technical Meeting of Institute of Electrical Engineers (Electronic Industry Material Technical Meeting, Dec. 19, 2003), EFM-03-44, P47 to 50, 2003”.

### SUMMARY OF THE INVENTION

There are a problem that KTC noise and charge sharing noise exist in a FD type output unit in related arts and a problem that high conversion gain is hardly obtained in a FG (floating gate) type which is the type not having KTC noise and charge sharing noise, as compared with the FD type.

It is desirable to obtain high conversion gain while suppressing KTC noise and charge sharing noise by arranging a drive transistor used in a carbon nanotube channel.

According to an embodiment of the invention, there is provided a solid-state imaging device including a signal charge detection unit which converts signal charges into voltage to be outputted, which have been obtained by photoelectrically converting incident light, and the signal charge detection unit arranges a drive transistor having a carbon nanotube channel over a channel region between an output gate and a reset gate of the solid-state imaging device through an insulating film.

In the solid-state imaging device according to an embodiment of the invention, potential of the channel including carbon nanotube of the drive transistor is modulated by signal charges transferred to the channel region under the channel of the carbon nanobube, accordingly, current flowing in the drive transistor is modulated and converted into a signal voltage to be read out, therefore, the drive transistor has high transcondutance (gm). In addition, the signal charge detection unit is small in size and has high sensitivity and high frequency characteristic (f-characteristic).

In the solid-state imaging device according to an embodiment of the invention, the signal charge detection unit is arranged continuously with the channel region (for example, CCD channel), and charge transfer from the signal charge detection unit to the reset gate is performed by CCD transfer (complete transfer), therefore, the there is an advantage that the device does not have KTC noise or charge sharing noise and will be a highly sensitive imaging device. Through the signal charge detection unit is basically a kind of the FG type, higher conversion gain than the FG type can be obtained.

Also in a solid-state imaging device according to an embodiment of the invention, transfer of signal voltage is performed by a gate of an amp transistor from the charge voltage conversion unit such as floating diffusion to the amp transistor, there is an advantage that the device does not have KTC noise or charge sharing noise and will be a high sensitive imaging device.

### BRIEF DESCRIPTION OF THE DRAWINGS

FIG. 1 is a configuration sectional-view showing a solid-state imaging device according to an embodiment (first embodiment) of the invention;

FIG. 2 is a configuration plan view showing the solid-state imaging device according to the embodiment (first embodiment) of the invention;

FIG. 3 is a schematic configuration view showing the solid-state imaging device according to the embodiment (first embodiment) of the invention;

FIG. 4 is a circuit diagram explaining a FD type;

FIG. 5 is a circuit diagram explaining a FG type;

FIG. 6 is a configuration plan view showing a solid-state imaging device according to an embodiment (second embodiment) of the invention; and

FIG. 7 is a block diagram showing an imaging apparatus according to an embodiment of the invention.

### DESCRIPTION OF THE PREFERRED EMBODIMENTS

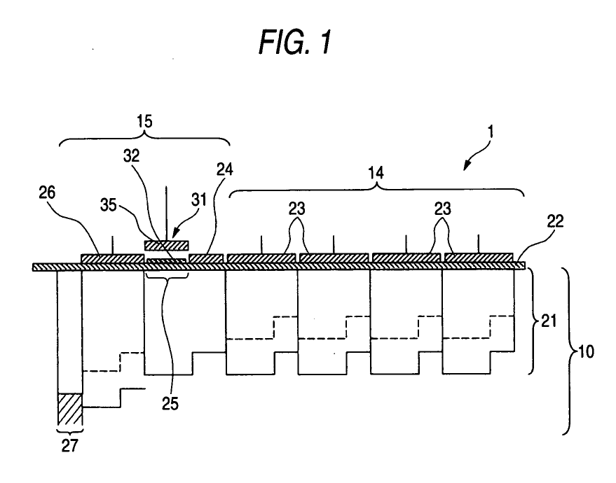

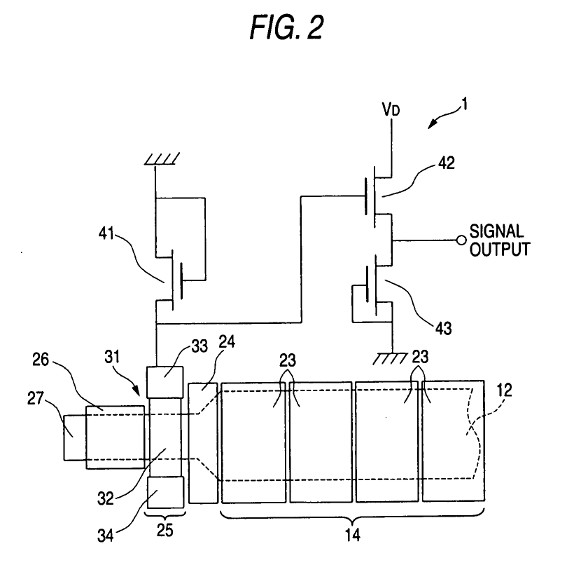

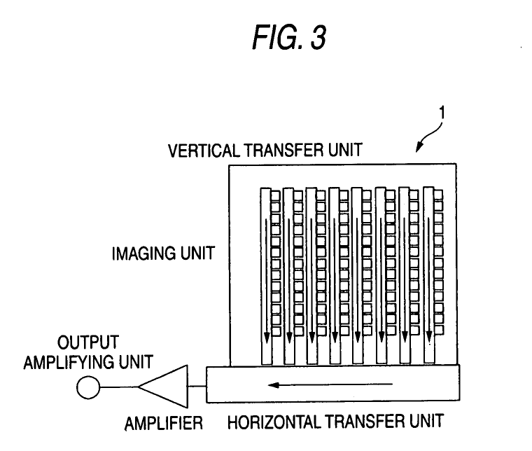

A solid-state imaging device according to an embodiment (first embodiment) of the invention will be explained with reference to configuration views of an output unit of the solid-state imaging device shown in FIG. 1 and FIG. 2 and a configuration view of the solid-state imaging device of FIG. 3.

An outline of the solid-state imaging device will be explained taking a CCD solid-state imaging device as an example. As shown in FIG. 3, a solid-state imaging device (CCD solid-state imaging device) 1 includes an imaging unit 13 having photoelectric conversion units 11 photoelectrically converting incident light and vertical transfer units 12 vertically transferring charges obtained by performing photoelectric conversion at the photoelectric conversion units 11, a horizontal transfer unit 14 horizontally transferring signal charges to an output side, which have been vertically transferred, and an output unit 15 converting signal charges outputted from the horizontal transfer unit 14 into voltage to be amplified.

The detail of the output unit 15 is shown in FIG. 1 and FIG. 2. A semiconductor substrate 10 is provided with the horizontal transfer unit 14 (for example, horizontal transfer CCDs) 14. The horizontal transfer unit 14 has a configuration in which transfer gates 23 are arranged on a channel region 21 formed in the semiconductor substrate 10 through an insulating film 22, and respective transfer gates 23 are connected to respective vertical transfer units though not shown. On an output side of the horizontal transfer unit on the semiconductor substrate 10, an output gate (horizontal output gate) 24, a signal charge detection unit 25, and a reset gate 26 are sequentially formed through the insulating film 22. The signal charge detection unit 25 includes, for example, a drive transistor 31.

In the drive transistor 31, a carbon nanotube channel 32 is provided over the insulating film 22 formed on the channel region 21. A source 33 is arranged at one side of the carbon nanotube channel 32, and a drain 34 is arranged at the other side of the carbon nanotube channel 32. A control gate 35 is installed over the channel 32 through an insulating film (not shown). The direction of the channel 32 is the direction crossing the charge transfer direction of the horizontal transfer unit 14 (vertical direction in the drawing). Therefore, positions of the source 33 and the drain 34 of the drive transistor 31 are over the insulating film 22 at positions of both sides sandwiching the cannel region 21.

A load MOS field effect transistor (FET) 41 is connected at the source 33 side of the drive transistor 31 and a load MOSFET 43 is connected through a drive MOSFET 42, which form source followers of two stages. Through two-stages source followers are formed in the embodiment, the number of stages of the source follower may be one stage, three stages or four stages. The load MOSFETs 41, 43 are taken as the embodiment, however, they do not have to be on-chip. In addition, the transistor does not have to be the MOSFET but may be a bipolar transistor, or an emitter follower and the like. The control gate 35 shown in FIG. 1 is not shown in FIG. 2 in consideration of clearness of the drawing.

The reset gate 26 is arranged at the side of the traveling direction of signal charges of the control gate 35 with a gap. A reset drain 27 is formed on the semiconductor substrate 10 at the opposite side of the drive transistor 31 of the reset gate 26.

In the solid-state imaging device 1, when signal charges transferred from the horizontal transfer unit 14 are transferred to the channel region 21 under the control gate 35 through the cannel region 21 under the horizontal output gate 24, potential change occurs at the channel region 21 according to a signal charge amount. The potential change occurring at the channel region 21 modulates a potential of the channel 32 of the drive transistor 31 by capacitive coupling. The current-voltage (I-V) characteristic of the drive transistor 31 tends to be the same as the current-voltage (I-V) characteristic of the MOSFET. Therefore, the channel region 21 functions as a gate electrode unit of the drive transistor 31. Accordingly, current flowing in the drive transistor 31 is converted into signal voltage by receiving modulation, and is outputted outside as signal output through the source follower.

In the embodiment, after reading out signal charges, the reset gate 26 is made to be High and charges are swept out from the channel region 21 to the reset drain 27. In the reset operation, it is also possible that potential is given to the Low-side of the control gate 35 and the potential of the channel region 21 is made shallow to promote complete transfer from the channel region 21 to the reset gate 26.

In the solid-state imaging device 1, the signal charge detection unit 25 is formed continuously with the horizontal transfer unit 14 through the horizontal output gate 24, in which charge transfer is performed from the signal charge detection unit 25 to the reset gate 26 by CCD transfer (complete transfer) Since there is not KTC noise or charge sharing noise, the device can be highly sensitive. Though the solid-state imaging device 1 is basically a kind of FG-type solid-state imaging devices, it is possible to obtain conversion gain higher than the FG-type.

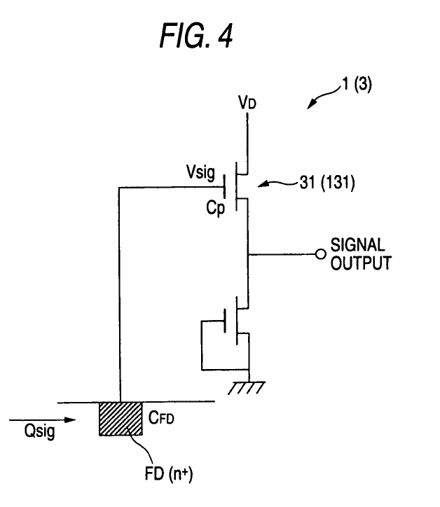

The reason thereof will be explained below. Here, as shown in FIG. 4, in the FD type, a potential change Vsig by a signal charge amount Qsig in the output transistor is given by a formula (1) . . . Vsig=Qsig/(CFD₊Cₚ). In this case, capacitance of the floating diffusion FD formed by n+ layer is denoted by CFD, and capacitance of the output transistor is denoted by Cp.

The floating diffusion FD shown in FIG. 4 is also formed on a pixel of a CMOS sensor. Also in the CMOS sensor, potential change Vsig by a signal charge amount Qsig in the output transistor is given by the formula (1) . . . Vsig=Qsig/(CFD₊Cₚ) in the same way as the FD type, and signal output is formed based on the potential change Vsig.

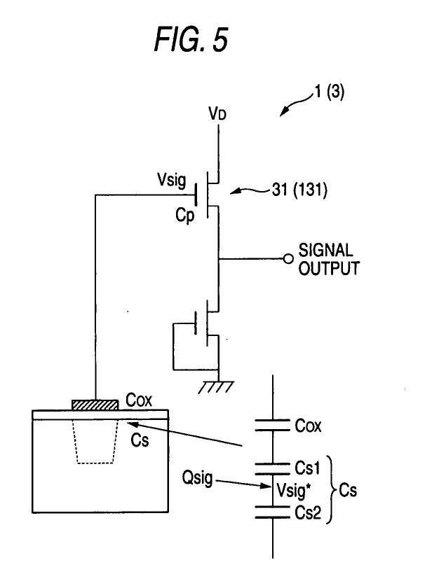

As shown in FIG. 5, in the FG type, when serial capacitance of CS1, Cox and Cp is Ct, a formula (2) . . . 1/Ct=1/Cs1+1/Cox+1/Cp can be obtained. In addition, relation between a formula (3) . . . Vsig*=Qsig/(Cs2+Ct) and a formula (4) . . . potential change in the output transistor Vsig=(Cs1+Cox)·Vsig*/(Cs1+Cox+Cp). Here, the formula (1) and the formula (4) are represented in a simple manner. For example, when estimating by assuming that CFD=Cp=Cs1=Cox=Cs2=1 (unit capacitance), a capacitance coefficient of the formula (1) is ½, and a capacitance coefficient of the formula (4) is ¼, as a result, conversion gain by the effect of capacitance in the FG type will be ½ of the FD type. This is the evaluation by the simple manner when capacitance components are the same, however, an actual value is apt to be close to the value.

Since the above solid-state imaging device 1 has a configuration in which Cox and Cp are shared in the FG type, capacitance component concerning conversion gain will decrease. When discussing in unit capacitance which is simplified as the above, ⅓ can be obtained, namely, an intermediate value between the FG type and the FD type can be obtained. That is, large conversion gain can be obtained as compared with the general FG type.

In the solid-state imaging device 1, the drive transistor 31 in which carbon nanotube is used as the channel 32 is formed. Though the drive transistor is formed by a silicon (Si) TFT can be considered, the transconductance “gm” of the drive transistor 31 in which carbon nanotube is used as the channel 32 is several dozen times as large as “gm” of the silicon TFT or a silicon bulk transistor having the same size. An amplifier having large gain as a source follower can be realized by the drive transistor 31 in which carbon nanotube is used as the channel 32.

In a pixel of the CMOS sensor having the floating diffusion FD shown in FIG. 4, an amp transistor 131 in which carbon nanotube is used as the channel is formed. Though a configuration in which such amp transistor 131 is formed by the silicon (Si) TFT can be considered, the transconductance “gm” of the amp transistor 131 in which carbon nanotube is used as the channel is several dozen times as large as “gm” of the silicon TFT or the silicon bulk transistor of the same size. Accordingly, an amplifier having large gain as a source follower can be realized by the amp transistor 131 in which carbon nanotube is used as the channel.

1/f noise which is thermal noise of the drive transistor 31 in which carbon nanotube is used as the channel 32 is smaller than that of the silicon transistor. Accordingly, the amplifier having high S/N can be realized.

Furthermore, the 1/f noise which is the thermal noise of the amp transistor 131 in which carbon nanotube is used as the channel is smaller than the silicon transistor. Accordingly, the amplifier having high S/N can be realized.

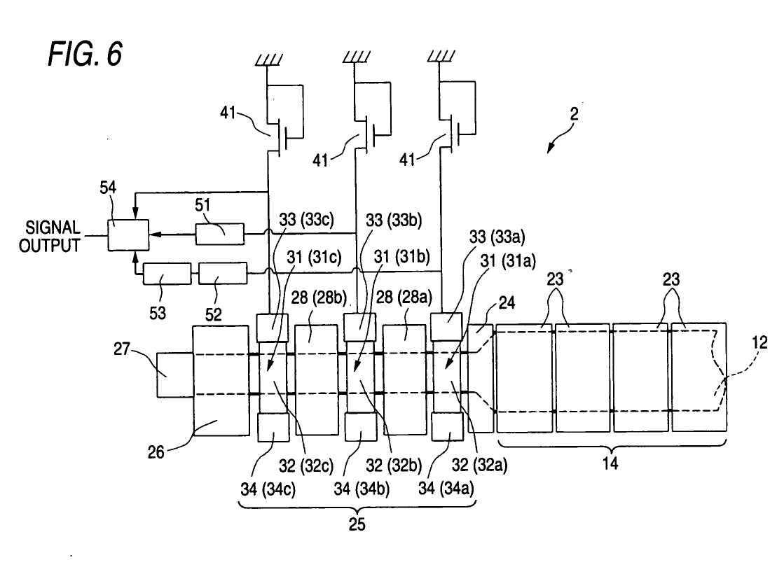

Next, a solid-state imaging device according to one embodiment (second embodiment) of the invention will be explained by a configuration plan view of an output unit of a solid-state imaging device shown in FIG. 6.

As shown in FIG. 6, a semiconductor substrate 10 is provided with the horizontal transfer unit 14 (for example, horizontal transfer CCDs) 14. The horizontal transfer unit 14 has a configuration in which transfer gates 23 are arranged on a channel region 21 formed in the semiconductor substrate 10 through an insulating film (not shown) and respective transfer gates 23 are connected to respective vertical transfer units though not shown. On an output side of the horizontal transfer unit 14 on the semiconductor substrate 10, a horizontal output gate 24, a signal charge detection unit 25, and a reset gate 26 are sequentially formed through the insulating film. Since the signal charge detection unit 25 is capable of performing nondestructive reading, for example, plural stages of drive transistors 31 (31a), 31 (31b), 31 (31c) are arranged, and transfer gates 28 (28a), 28 (28b) are formed between respective drive transistors 31(31a), 31 (31b), 31 (31c). The reset gate 26 is formed in the traveling direction of signal charges of the control gate 35 with a gap. A reset drain 27 is formed on the semiconductor substrate 10 at the opposite side of the drive transistor 31 of the reset gate 26.

Channels 32a to 32c made of carbon nanotube are provided at respective drive transistors 31a to 31c over an insulating film formed on the channel region 21. Sources 33a to 33c are arranged at one side of the carbon nanotube channels 32a to 32c and drains 34a to 34c are arranged at the other side of the respective carbon nanotube channel 32a to 32c. Control gates (not shown) are installed over the channels 32 over an insulating film (not shown). The configuration is the same as the control gate 35 explained with reference to FIG. 1. The direction of respective channels 32a to 32c is the direction crossing the charge transfer direction of the horizontal transfer unit 14 (vertical direction in the drawing). Therefore, positions of the sources 33 and the drains 34 of the drive transistor 31 are over the insulating film at positions of both sides sandwiching the cannel region 21.

Load MOS field effect transistors (FET) 41 are connected at the side of sources 33 of the drive transistors 31 to form source followers. Through two-stages source followers are formed in the embodiment, the number of stages of the source follower may be one stage or plural stages. The load MOSFETs 41 are taken as the embodiment, however, they are not always be on-chip. In addition, the transistor is not always the MOSFET but may be a bipolar transistor, or an emitter follower and the like. Furthermore, delay circuits 51, 52 and 53 are provided at output units of respective drive transistors, which perform addition to be averaged by an adder 54, thereby performing output. A so-called distributed floating gate amplifier is formed.

In the solid-state imaging device 2, assume that signals are transferred in the horizontal transfer unit 14 from right to left in the drawing. At this time, when a signal amount is A in the channel region 21 under respective drive transistors 31, assume that a signal amount A* is generated by the drive transistor 31a. Assuming that the horizontal transfer units 14 and the delay circuits 51 to 53 operate in the same clock, concerning signals transmitted nondestructively through the channel region 21 under the drive transistor 31a, the signal amount A* is generated by the drive transistor 31a. Similarly, the signal amount A* is generated by respective drive transistors 31b, 31c. The generated respective signal amounts A* are read in the adder 54, being added and averaged through the delay circuits 51 to 53. Since respective signal amounts A* are read in the adder 54 through the delay circuits 51 to 53, the signal amounts A* are read at the same time. That is to say, the delay circuits 51 to 53 are adjusted so that respective signal amounts A* are read in the adder 54 at the same time. Accordingly, since signals are read out nondestructively without losing the signal amounts at respective drive transistors 31a to 31c, for example, when there are M-stages of amplifying stages, the signal amount will be M×(A*/A). From the characteristic of the drive transistor 31 in which carbon nanotube is used as the channel 32, when assuming that the signal amount A*/signal amount A≅1, S/N will be √M times by sampling of M-times. In the embodiment, there are three stages (drive transistors 31a to 31c) of amplifying stages, therefore, √3 times increase of S/N will be possible.

Next, a method of manufacturing the solid-state imaging device according to an embodiment of the invention will be explained below. The same numerals are put to respective components to be explained in the method of manufacturing, which are the same as components explained in the first embodiment.

For example, a normal N-type silicon substrate is used for the semiconductor substrate 10 which forms the solid-state imaging device. First, an N-type epitaxial layer is formed on the semiconductor substrate 10 to have a thickness of, for example, 10 μm. An impurity profile for forming the CCD units is formed on the epitaxial layer. That is, the channel region 21, a channel stop unit, photoelectric conversion units 11 and the like are formed.

Next, the insulating film 22 (gate insulating film) is formed on the epitaxial layer. For example, the film is formed by a silicon oxide film having a thickness of 50 nm by a thermal oxidation method at 900° C.

Next, after forming, for example, a polysilicon film is formed for forming respective gates, the polysilicon film is patterned by a lithography technology, an etching technology and the like to form respective gates (for example, a CCD transfer electrode of the vertical transfer unit 12, a CCD transfer electrode of the horizontal transfer unit 14 and a horizontal output electrode of the horizontal output gate 24, a reset electrode of the reset gate 26 and the like). Furthermore, an electrode of the MOS transistor at the output unit is formed. The formation of the electrode can be performed at the same time as the formation of the above electrodes. Next, source/drain regions of respective MOS transistors are formed.

Next, the drive transistor 31, the source 33, and the drain 34 are formed. For example, after a metal film or an alloy film such as titanium (Ti), tungsten (W), platinum (Pt) and the like is formed, the metal film is processed. Subsequently, the channel 32 is formed by forming carbon nanotube. For the formation, for example, a chemical vapor deposition (CVD) and the like can be used. An insulating film (not shown) is formed over the channel 32. For example, the film is formed by depositing silicon oxide by the CVD method. After that, an conductive layer for forming the control gate 35 is formed by, for example, a tungsten silicide (WSi), aluminum (Al) and the like is formed, then, patterned to obtain the control gate 35. Furthermore, an insulating film is formed over the whole surface.

Next, after a contact hole is formed by a normal formation technology of the contact hole, metal wiring is formed by, for example, aluminum, copper and the like. A shielding film having openings over the photoelectrical conversion units 11 is formed, if necessary. After a planarizing film, a passivation film and the like are formed, color filters, on-chip lenses and the like are formed to complete the solid-state imaging device 1.

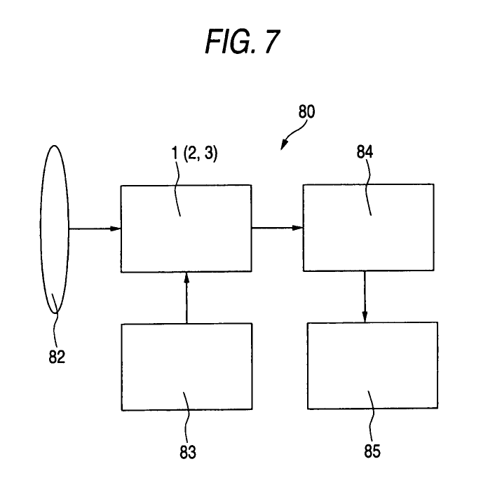

Next, an imaging apparatus according to an embodiment of the invention will be explained with reference to a block diagram of FIG. 7.

As shown in FIG. 7, an imaging apparatus 80 includes the solid-state imaging device 1, 2 or 3 according to an embodiment of the invention. An imaging optical system 82 which images subjects is provided at the side of gathering light, and a signal processing circuit 84 processing signals into images, which have been photoelectrically converted at the solid-state imaging device 1, 2 or 3. The image signals processed by the signal processing circuit 84 are stored by an image storage unit 85. It is also preferable that the image storage unit 85 is provided outside.

Since the solid-state imaging device 1, 2 or 3 according to an embodiment of the invention is used in the imaging apparatus 80, there is not KTC noise or charge sharing noise, therefore, there is an advantage that the imaging apparatus can obtain high-quality images. Additionally, there is an advantage that conversion gain higher than the FG type can be obtained.

The imaging apparatus 80 is not limited to the above configuration, and can be applied to any configuration of the imaging apparatus using the solid-state imaging device. For example, the apparatus means a camera or a portable apparatus including an imaging function. In addition, “imaging” includes not only normal picking-up of images at the time of taking pictures by the camera but also fingerprint detection and the like as an extended meaning.

It is preferable that the solid-state imaging devices 1, 2 or 3 has a shape formed by one chip and also preferable that it has a module shape having an imaging function in which the imaging unit and the signal processing unit or the optical system are packaged integrally.

It should be understood by those skilled in the art that various modifications, combinations, sub-combinations and alterations may occur depending on design requirements and other factors insofar as they are within the scope of the appended claims or the equivalents thereof.

What is claimed is:

1. A solid-state imaging device, comprising:
a signal charge detection unit converting signal charges into voltage to be outputted, which have been obtained by photoelectrically converting incident light,
wherein the signal charge detection unit arranges a drive transistor having a carbon nanotube channel over a channel region between an output gate and a reset gate of the solid-state imaging device through an insulating film.

2. The solid-state imaging device according to claim 1,
wherein the drive transistor includes
the carbon nanotube channel crossing the channel region,
a source at one side of the carbon nanotube channel and
a drain at the other side of the carbon nanotube channel.

3. The solid-state imaging device according to claim 1,
wherein the channel includes a control gate through an insulating film.

4. The solid-state imaging device according to claim 3,
wherein the reset gate is installed at the traveling direction side of signal charges of the control gate with a gap.

5. The solid-state imaging device according to claim 3,
wherein a reset drain is included at the opposite side of the control gate of the reset gate.

6. The solid-state imaging device according to claim 1,
wherein a potential of the channel made of carbon nanotube of the drive transistor is modulated by signal charges transferred to the channel under the control gate, accordingly, current flowing in the drive transistor is modulated and converted into signal voltage to be read out.

7. The solid-state imaging device according to claim 1,
wherein a plurality of drive transistors are arranged between the output gate and the reset gate, and transfer gates are arranged between the drive transistors over the channel region.

8. An imaging apparatus, comprising:
a solid-state imaging device including a signal charge detection unit converting charges into voltage to be outputted, which have been obtained by photoelectrically converting incident light,
wherein the signal charge detection unit arranges a drive transistor having a channel made of carbon nanotube over a channel region between an output gate and a reset gate of the solid-state imaging device through an insulating film.
